(19) United States
(12) Patent Application Publication
(10) Pub. No.: US 2008/0253069 A1
(43) Pub. Date: Oct. 16, 2008

(54) Key fixing structure and electronic device using the same

(75) Inventors: Shan-Wei Hong, Sujou City (CN); Wei-Min Su, Sujou City (CN)

Correspondence Address: BACON & THOMAS, PLLC, 625 SLATERS LANE, FOURTH FLOOR, ALEXANDRIA, VA, 22314-1176, US

(73) Assignee: Qisda Corporation, Taoyuan Shien (TW)

(21) Appl. No.: 12/078,377

(22) Filed: Mar. 31, 2008

(30) Foreign Application Priority Data
Apr. 10, 2007 (TW) 96112591

(51) Int. Cl. H05K 5/00

(52) U.S. Cl. 361/680

(57) ABSTRACT

A key fixing structure and an electronic device using the same are provided. The key fixing structure is used for fixing several keys in the electronic device having at least one fixing groove. The key fixing structure includes a planar main body and at least one fixing portion. The planar main body has several installing spaces, and the keys are correspondingly disposed in the installing spaces. The fixing portion is provided with an included angle relative to the planar main body. When the fixing portion is received in the fixing groove, the key fixing structure is firmly disposed in the electronic device.

### BACKGROUND OF THE INVENTION

1. Field of the Invention

The invention relates in general to a key fixing structure and an electronic device using the same, and more particularly to a key fixing structure and an electronic device using the same for fixing several keys in the electronic device.

2. Description of the Related Art

Consumer electronic products are getting more and more attention on the market. Different new products are brought forth continuously to meet various needs of customers. For example, as mobile phones are getting popular rapidly, manufacturers are trying to integrate multiple functions into single mobile phone. Thus, mobile phones are now equipped with functions of portable music players, cameras and voice recorders, etc. In view of the demands of the market for light weight, small size and multi-functional mobile phones, while integrating various functions, the volume and the weight of the product have to be considered. Therefore, how to effectively arrange different elements in the extreme limited space is one of the important research directions for manufacturers nowadays.

Generally speaking, a mobile phone is operated by a user through many keys. These keys are fixed by way of fitting the keys in a fixing element disposed in the housing of the mobile phone. Referring to FIG. 1, a fixing element of a conventional mobile phone is illustrated. The fixing element 10 is a planar metal plate having several extending parts 11 extending therefrom. Each extending part 11 has a fixing hole 12 therein for fitting with a pin (not illustrated) disposed on the housing of the mobile phone, such that the fixing element 10 can be connected onto the housing. However, the edge of the fixing element 10 needs to have a width at least including a first width D1 of the fixing hole 12. Besides that, for ensuring the fixing strength, the width of the edge needs to further include a second width D2 for holding the fixing hole 12. Therefore, the extending parts 11 are more extended from the edge of the fixing element 10, which increases the width and the length of the fixing element 10. Overall, the area required by the extending parts 11 of the fixing element 10 is inevitably increased, limiting the available area for key design.

### SUMMARY OF THE INVENTION

The invention is directed to a key fixing structure and an electronic device using the same. A fixing portion and a planar main body of the key fixing structure have an included angle therebetween, so that the area of the planar main body of the key fixing structure can be relatively increased, and the area available for disposing the keys can be increased accordingly. Further, the operational convenience is improved.

According to one aspect of the present invention, a key fixing structure for fixing several keys in an electronic device is provided. The electronic device has at least one fixing groove. The key fixing structure includes a planar main body and at least one fixing portion. The planar main body has several installing spaces located therein. The keys are correspondingly disposed in the installing spaces. The fixing portion is provided with an included angle relative to the planar main body. When the fixing portion is received in the fixing groove, the key fixing structure is firmly disposed in the electronic device.

According to another aspect of the present invention, an electronic device including several keys, a key fixing structure and a housing is provided. The key fixing structure used for fixing the keys in the electronic device includes a planar main body and at least one fixing portion. The planar main body has several installing spaces located therein. The keys are correspondingly disposed in the installing spaces. The fixing portion is provided with an included angle relative to the planar main body. The housing has at least one fixing groove corresponding to the fixing portion. When the fixing portion is received in the fixing groove, the key fixing structure is firmly disposed in the housing.

The invention will become apparent from the following detailed description of the preferred but non-limiting embodiment. The following description is made with reference to the accompanying drawings.

### BRIEF DESCRIPTION OF THE DRAWINGS

FIG. 1 (Prior Art) is a perspective view of a fixing element of a conventional mobile phone;

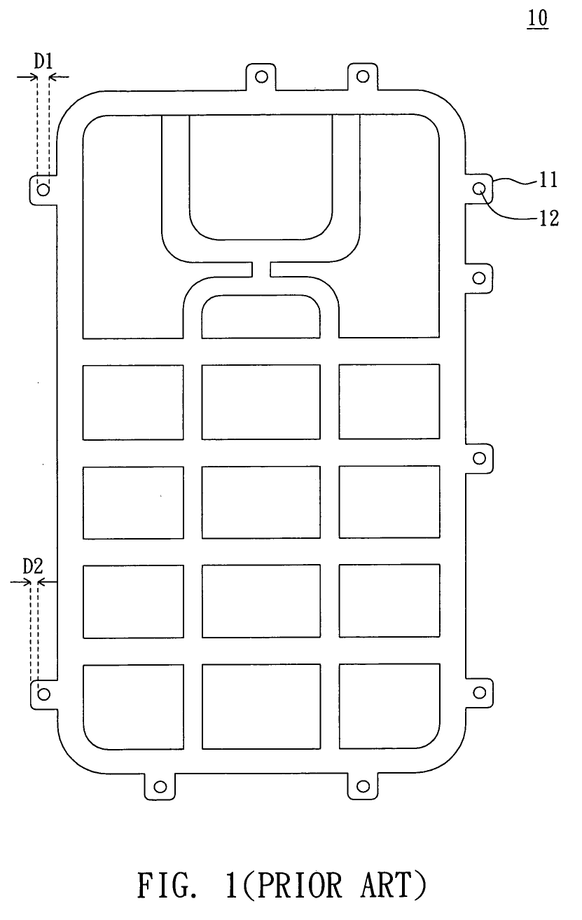

FIG. 2 is an exploded view of an electronic device according to a preferred embodiment of the invention;

FIG. 3 is a perspective view of the key fixing structure in FIG. 2;

FIG. 4 is a perspective view of the key fixing structure and the housing in FIG. 2 being connected to each other; and

FIG. 5 is a cross-sectional view of the key fixing structure and the housing taken along line A-A′ of FIG. 4.

### DETAILED DESCRIPTION OF THE INVENTION

The invention is exemplified by a preferred embodiment disclosed below. The embodiment of the invention is for the purpose of elaboration not for limiting the scope of protection of the invention. Further, unnecessary elements are omitted in the embodiment to clearly show the technical characteristics of the invention.

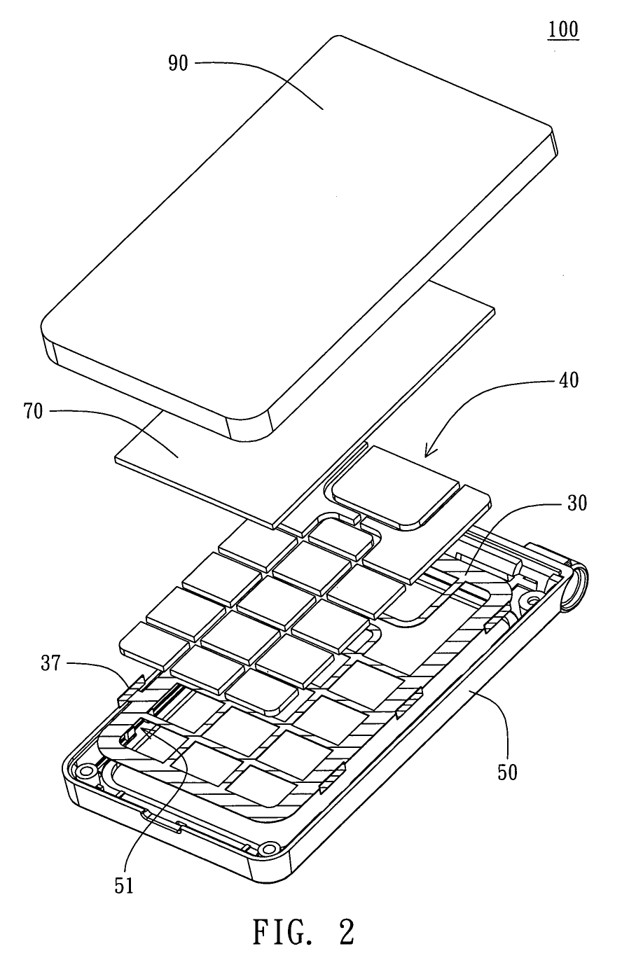

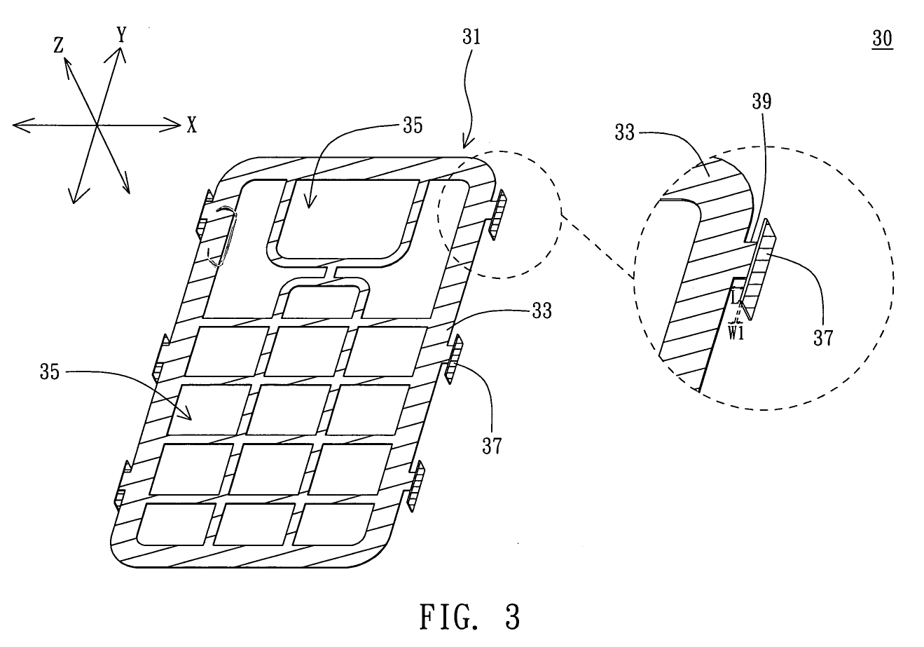

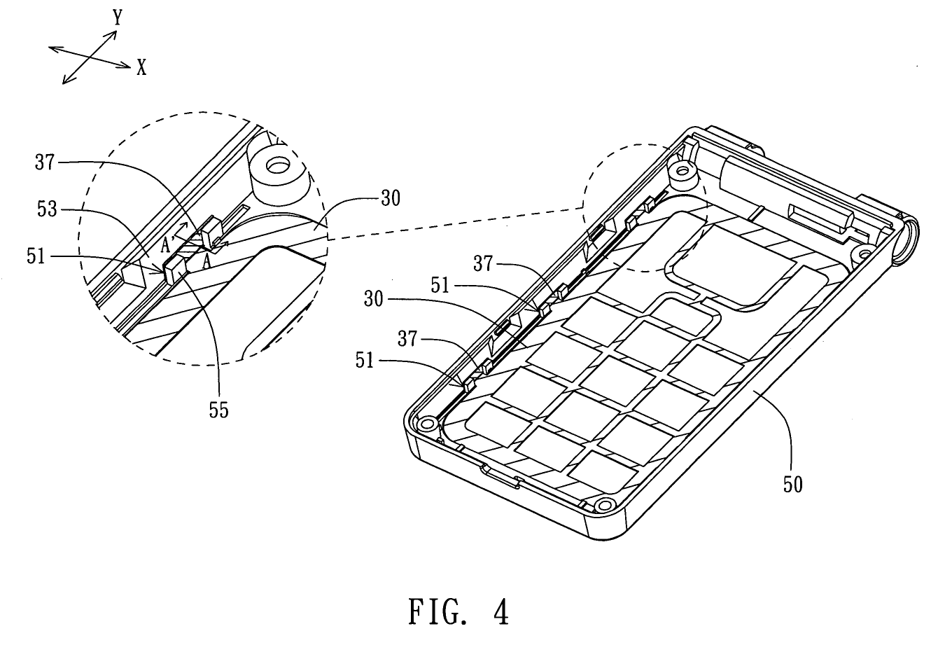

Please refer to FIGS. 2˜4 at the same time. FIG. 2 is an exploded view of an electronic device according to a preferred embodiment of the invention; FIG. 3 is a perspective view of the key fixing structure in FIG. 2; and FIG. 4 is a perspective view of the key fixing structure and the housing in FIG. 2 being connected to each other. The electronic device 100 includes several keys 40, a key fixing structure 30 and a housing 50. The key fixing structure 30 used for fixing the keys 40 includes a planar main body 31 and at least one fixing portion 37. As shown in FIG. 3, the planar main body 31 has several installing spaces 35 located therein, a disposition plane 33, and the keys 40 are correspondingly disposed in the installing spaces 35. The disposition plane of the fixing portion 37 and the disposition plane 33 of the planar main body 31 are not parallel; the fixing portion 37 is provided with an included angle relative to the planar main body 31. In the present embodiment, the included angle is preferably a 90-degree angle or any other angle substantially equal to 90 degrees. The housing 50 has at least one fixing groove 51 that corresponds to the location of the fixing portion 37. When the fixing portion 37 is received in the fixing groove 51, the key fixing structure 30 is firmly disposed in the housing 50, as shown in FIG. 3.

Furthermore, the disposition plane 33 in FIG. 3 is parallel to the XY plane formed by direction x and direction y for example. The fixing portion 37 is parallel to the YZ plane formed by direction y and direction z for example. In other words, the fixing portion 37 is substantially perpendicular to the planar main body 33. Hence, the projection area of the fixing portion 37 on the XY plane is decreased, the width of the planar main body 31 in direction x is increased, and the area of the keys 40 can be increased. Consequently, the convenience of pressing the keys 40 for users is improved.

In the present embodiment, the planar main body 31 of the key fixing structure 30 is preferably a plate of rigid material, for firmly supporting the keys 40. The planar main body 31 has several fixing portions 37 that are disposed adjacent to the edge of the planar main body 31 and are spaced away from each other. Thus the planar main body 31 is equally and uniformly connected with the housing 50. In addition to that, the fixing portion 37 is preferably a rectangular plate. The key fixing structure 30 further includes a connecting arm 39 for connecting the fixing portion 37 and the edge of the planar main body 31. The connecting arm 39 keeps the fixing portion 37 away from the edge of the planar main body 31 by a distance L. The planar main body 31, the connecting arm 39 and the fixing portion 37 are preferably formed in unity and made of the same rigid material for improving endurance.

Referring to FIG. 4, the electronic device 100 in the present embodiment has several fixing grooves 51 that correspond to the locations of the fixing portions 37, and each fixing portion 37 is correspondingly connected to one fixing groove 51. In addition to that, the housing 50 further includes a lateral wall 53 and at least one pair of protrusions 55. The fixing groove 51 is formed between the lateral wall 53 and the pair of protrusions 55.

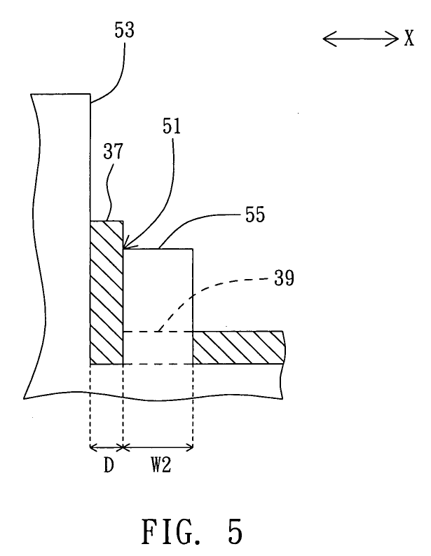

Please refer to FIG. 4 and FIG. 5 at the same time. FIG. 5 is a cross-sectional view of the key fixing structure and the housing taken along line A-A′ of FIG. 4. In the present embodiment, the fixing groove 51 has a connecting thickness D that is preferably equal to a thickness W1 of the fixing portion 37 (the thickness W1 is illustrated in FIG. 3). Therefore, when the fixing portion 37 is received in the fixing groove 51, the lateral wall 53 and the pair of protrusions 55 are contacted with the fixing portion 37. Hence the fixing portion 37 is firmly wedged into the fixing groove 51 for preventing the movement of the fixing portion 37 relative to the lateral wall 53 and the pair of protrusions 55 in direction x. On the other hand, a thickness W2 of the pair of protrusions 55 is preferably equal to the distance L between the fixing portion 37 and the edge of the planar main body 31 (the distance L is illustrated in FIG. 3). When the fixing portion 37 is received in the fixing groove 51, the pair of protrusions 55 contact with two sides of the connecting arm 39 for preventing the movement of the connecting arm 39 relative to the pair of protrusions 55 in direction y.

Furthermore, the electronic device 100 according to the preferred embodiment of the invention can be exemplified by a mobile phone or a personal digital assistant (PDA). The electronic device 100 further includes a circuit board 70 and a back cover 90. When the keys 40 are pressed by user, the circuit board 70 outputs an electric signal to other element (not illustrated), like an arithmetic control unit, a storage unit or a display unit. The electronic device 100 is operated by a user through this manner. The back cover 90 envelops the key fixing structure 30, these keys 40 and the circuit board 70 for protecting these elements and maintaining esthetics of the electronic device 100. In the electronic device 100 of the present embodiment, the width of the planar main body 31 in direction x is increased by the disposition of the fixing portion 37 perpendicular to the planar main body 31. The disposition area of the keys 40 is increased accordingly, and the operational convenience of the electronic device 100 is improved.

In the key fixing structure and the electronic device according to the above-described preferred embodiment of the invention, the key fixing structure for fixing several keys includes the planar main body and at least one fixing portion. Because the fixing portion is perpendicular to the plane, the width of the planar main body can be effectively increased without changing the volume of the housing, and the area available for disposing the keys is therefore increased. The advantages thereof are as follows. The installing spaces are enlarged, and the area of the keys can be increased relatively, thus facilitating the convenience of operating the electronic device. Further, because the planar main body, the connecting arm and the fixing portion are formed in unity, the key fixing structure according to the preferred embodiment has the virtues of simple structure and simple fabricating process. Moreover, the cost is not significantly increased because the electronic device need not be added with any new elements. In addition to that, the key fixing structure is firmly connected with the housing through the tight contact of the pair of protrusions and the lateral wall with the connecting arm and the fixing portion. The key fixing structure is therefore firmly disposed in the electronic device, and the movement of the key fixing structure is avoided. Overall, the keys are steadily disposed in the electronic device, and the product quality is improved.

While the invention has been described by way of example and in terms of a preferred embodiment, it is to be understood that the invention is not limited thereto. On the contrary, it is intended to cover various modifications and similar arrangements and procedures, and the scope of the appended claims therefore should be accorded the broadest interpretation so as to encompass all such modifications and similar arrangements and procedures.

What is claimed is:

1. A key fixing structure for fixing a plurality of keys in an electronic device having at least one fixing groove, the key fixing structure comprising:
a planar main body having a plurality of installing spaces located therein, wherein the keys are correspondingly disposed in the installing spaces; and
at least one fixing portion provided with an included angle relative to the planar main body;
wherein when the fixing portion is received in the fixing groove, the key fixing structure is firmly disposed in the electronic device.

2. The key fixing structure according to claim 1, wherein the fixing portion is disposed adjacent to an edge of the planar main body.

3. The key fixing structure according to claim 2 further comprising a connecting arm for connecting the fixing portion and the edge of the planar main body.

4. The key fixing structure according to claim 3, wherein the fixing portion has a thickness substantially equal to a connecting thickness of the fixing groove so that the fixing portion is firmly wedged into the fixing groove.

5. The key fixing structure according to claim 1, wherein the included angle is substantially equal to 90 degrees.

6. The key fixing structure according to claim 1, wherein the fixing portion is a rectangular plate.

7. The key fixing structure according claim 1, wherein the planar main body is a plate of rigid material.

8. An electronic device, comprising:
a plurality of keys;
a key fixing structure for fixing the keys in the electronic device comprising:
a planar main body having a plurality of installing spaces located therein, wherein the keys are correspondingly disposed in the installing spaces; and
at least one fixing portion provided with an included angle relative to the planar main body; and
a housing having at least one fixing groove corresponding to the fixing portion;
wherein when the fixing portion is received in the fixing groove, the key fixing structure is firmly disposed in the housing.

9. The electronic device according to claim 8, wherein the fixing portion is disposed adjacent to an edge of the planar main body.

10. The electronic device according to claim 8, wherein the included angle is substantially equal to 90 degrees.

11. The electronic device according to claim 8 further comprising a connecting arm for connecting the fixing portion and the edge of the planar main body.

12. The electronic device according to claim 11, wherein the housing comprises:
a lateral wall; and
at least one pair of protrusions, wherein the fixing groove is formed between the lateral wall and the pair of protrusions.

13. The electronic device according to claim 12, wherein when the fixing portion is wedged into the fixing groove, the pair of protrusions is located at two sides of the connecting arm and contacts with the connecting arm.

14. The electronic device according to claim 8, wherein the fixing groove has a connecting thickness substantially equal to a thickness of the fixing portion so that the fixing portion is firmly wedged into the fixing groove.

15. The electronic device according to claim 8, wherein the fixing portion is a rectangular plate.

16. The electronic device according to claim 8, wherein the planar main body is a plate of rigid material.

17. The electronic device according to claim 8, wherein the device is a mobile phone or a personal digital assistant (PDA).
